(19) United States
(12) Patent Application Publication
(10) Pub. No.: US 2010/0148637 A1
(43) Pub. Date: Jun. 17, 2010

(54) ACOUSTIC RESONATOR AND ITS FABRICATING METHOD

(75) Inventor: Kei Satou, Miyagi (JP)

Correspondence Address: K&L Gates LLP, P. O. BOX 1135, CHICAGO, IL, 60690, US

(73) Assignee: SONY CORPORATION, Tokyo (JP)

(21) Appl. No.: 12/095,305

(22) PCT Filed: Nov. 28, 2006
(86) PCT No.: PCT/JP2006/023707

§ 371 Date: May 28, 2008

(30) Foreign Application Priority Data
Dec. 1, 2005 (JP) P2005-347450
Nov. 17, 2006 (JP) P2006-311113

(51) Int. Cl. H01L 41/04; B05D 5/12

(52) U.S. Cl. 310/367; 427/100

(57) ABSTRACT

A piezoelectric layer has a multilayer structure including a tensile stress layer and a compression stress layer. The mechanical strength of the piezoelectric layer is increased to prevent the occurrence of cracks and to realize a high electromechanical coupling coefficient. An acoustic resonator 1 includes a first electrode 13 including at least one conductive layer, a piezoelectric layer 14 including a plurality of layers, the piezoelectric layer 14 being formed adjacent to the top face of the first electrode 13, and a second electrode 15 including at least one conductive layer, the second electrode 15 being formed adjacent to the top face of the piezoelectric layer 14. The piezoelectric layer 14 includes a tensile compression layer 23 in which tensile stress is present and compression stress layers 21 and 25 in which compression stress is present. The tensile stress in the tensile stress layer 23 and the compression stress in the compression stress layers 22 and 25 are adjusted to cancel each other.

### TECHNICAL FIELD

The present invention relates to an acoustic resonator and its fabricating method for preventing damage to a piezoelectric layer.

### BACKGROUND ART

In recent years, as cellular phones and personal mobile information terminals (PDA: Personal Digital Assistance) have become more sophisticated and faster, there has been an increasing demand to reduce the size and cost of high-frequency filters which are contained in these communication devices and which operate in a range from a few hundred MHz to a few GHz. A potential candidate for a high-frequency filter satisfying the demand is a filter using a thin film bulk acoustic resonator (abbreviated as FBAR hereinafter), which can be formed using semiconductor manufacturing techniques.

As a representative example of FBAR, there is a structure called an air bridge type (e.g., see K. M. Lakin, “Thin Film Resonators and Filters”, Proceedings of the 1999 IEEE Ultrasonics Symposium, Vol. 2, p. 895-906, October 1999 (hereinafter referred to as document 1)). This structure will be described using FIG. 9. Part (1) of FIG. 9 is a plan layout view, and part (2) of FIG. 9 is a schematic sectional view taken along the line X-X′ of part (1) of FIG. 9.

As shown in FIG. 9, a lower electrode 322 with a thickness of approximately 0.1 μm to approximately 0.5 μm is formed on a supporting substrate 320 made of high-resistance silicon or high-resistance gallium arsenide so as to enclose an air layer 321 with a thickness of approximately 0.5 μm to approximately 3 μm. On the lower electrode 322, a piezoelectric layer 323 with a thickness of approximately 1 μm to approximately 2 μm and an upper electrode 324 with a thickness of approximately 0.1 μm to approximately 0.5 μm are formed, whereby a thin film bulk acoustic resonator (FBAR) 100 is configured. The lower electrode 322, the piezoelectric layer 323, and the upper electrode 324 are sequentially formed using a sputter deposition technique and various etching techniques using resist as a mask, which are known in the semiconductor manufacturing field.

As the material of the foregoing electrodes, a metal material such as molybdenum, tungsten, tantalum, titanium, platinum, ruthenium, gold, aluminum, copper, or the like is used. As the piezoelectric material, for example, aluminum nitride (AlN), zinc oxide (ZnO), cadmium sulfide, lead zirconate titanate [Pb(Zr, Ti)O₃: PZT], or the like used.

Since the air layer 321 is formed immediately below an area where the upper electrode 324 and the lower electrode 322 spatially overlap each other (that is, an area where the structure operates as an FBAR), as in the upper electrode 324, the lower electrode 322 also has a boundary face in contact with air. The air layer 321 is formed by removing, by means of etching, a silicon dioxide film, a phosphosilicate glass (PSG) film, a borophosphosilicate glass (BPSG) film, an SOG (Spin on glass) film, or the like, which is formed to have the shape of the air layer 321 on the top face of the supporting substrate 320, using a fluoride (HF) solution through a via hole 326.

Next, an outline of the operation of the FBAR will be described. When a temporally changing electric field is generated inside the piezoelectric layer 323 by applying an alternating voltage between the upper electrode 324 and the lower electrode 322, the piezoelectric layer 323 converts part of electrical energy into mechanical energy in the form of an elastic wave (hereinafter referred to as an acoustic wave). This mechanical energy propagates in a thickness direction of the piezoelectric layer 323, which is a direction perpendicular to an electrode face, and is reconverted into electrical energy.

In this electrical/mechanical energy converting process, there is a specific frequency with excellent efficiency. When an alternating voltage with this frequency is applied, the acoustic resonator (hereinafter referred to as the FBAR; FBAR: Film Bulk Acoustic Resonator) exhibits extremely low impedance. This specific frequency is generally referred to as a resonant frequency (γ). The value of the resonant frequency is given by, as linear approximation in which the existence of the upper electrode 324 and the lower electrode 322 is ignored, γ=V/(2t) where V is the speed of the acoustic wave in the piezoelectric layer 323 and t is the thickness of the piezoelectric layer 323. Assuming that the wavelength of the acoustic wave is λ, the expression V=γλ holds true, and hence t=λ/2. This means that the acoustic wave induced in the piezoelectric layer 323 is repeatedly reflected up and down at the piezoelectric/electrode boundary faces, and a standing wave corresponding to a half-wavelength is formed. In other words, when the frequency of the acoustic wave in which a standing wave with a half-wavelength is generated matches the frequency of the alternating voltage, this frequency is the resonant frequency γ.

As an electronic device using the fact that the impedance of the FBAR is extremely small at the foregoing resonant frequency, a band-pass filter which includes a plurality of FBARs arranged in a ladder configuration and which only allows passage of electrical signals within a desired frequency band with low loss is disclosed in document 1.

In order to set a wide frequency pass-band in this filter, it is necessary to have a large difference between the resonant frequency and the half-resonant frequency of the FBARs. In other words, it is necessary to increase an electromechanical coupling coefficient. As means for achieving this, a method of allowing tensile stress to uniformly exist in the entirety of the piezoelectric layer is empirically known. In addition, it is disclosed that the electromechanical coupling coefficient can be increased using compression stress, which is in the opposite direction from tensile stress (e.g., see Japanese Unexamined Patent Application Publication No. 2005-124107).

However, as shown in FIG. 6, in an FBAR 210 in which a lower electrode 213 and a piezoelectric layer 214 in which tensile stress or compression stress is uniformly present are formed on a supporting substrate 211 with an air layer 212 provided therebetween, the piezoelectric layer 214 is bent in a concave shape (or a convex shape). As a result, as shown in FIG. 7, a crack 216 occurs in the piezoelectric layer 214, starting at point C where the piezoelectric layer 214 is bent. Alternatively, as shown in FIG. 8, cracks 217 occur in the piezoelectric layer 214, starting at peripheral ends of via holes 231. Therefore, the mechanical strength of the FBAR 210 is significantly reduced. Also, tips of the cracks 216 and 217 reach areas immediately below the upper electrode 215 or an FBAR (not shown) formed next to the FBAR 210, and there is a problem that the electrical characteristics of a filter using the FBARs is significantly degraded.

According to the experimental result obtained by the inventor of the present invention, in a case where tensile stress is 200 MPa and an aluminum nitride (AlN) film with a thickness of 1 μm is used, regardless of the planar shape of via holes, the rate of cracks occurring in FBARs is 70%, which is a high value. Also, in a case where compression stress is −350 MPa and an aluminum nitride (AlN) film with a thickness of 1 μm is used, regardless of the planar shape of via holes, the rate of cracks occurring in FBARs is 60%, which is also a high value.

However, FBARs constituting a band-pass filter are required to have an electromechanical coupling coefficient of 5% or higher. As a stress value satisfying this, the inventor of the present application has discovered from the experiment the fact that tensile stress of 300 MPa or greater or compression stress of 300 MPa or greater is necessary.

As has been described above, although the FBARs with a so-called air bridge structure have the problem of cracks occurring in the piezoelectric layer, since the air layer is positioned on the top face of the supporting substrate, the FBARs can be easily mounted together with a monolithic microwave integrated circuit (MMIC) or a silicon integrated circuit (SiIC). This feature is appealing in terms of satisfying the market's demands of reducing the size and enhancing the functions. Therefore, FBARs with the foregoing air bridge structure that can prevent the occurrence of cracks and that has a wide frequency pass-band, that is, a large electromechanical coupling coefficient, have been strongly demanded.

A problem to be solved is the point that, in an acoustic resonator with an air-bridge structure, a high electromechanical coupling coefficient cannot be realized without producing cracks in a piezoelectric layer.

It is an object of the present invention to prevent, in a piezoelectric layer with a multilayer structure including a tensile stress layer and a compression stress layer, the occurrence of cracks by increasing the mechanical strength of the piezoelectric layer and to realize a high electromechanical coupling coefficient.

### DISCLOSURE OF INVENTION

An acoustic resonator of the present invention includes a first electrode including at least one conductive layer, a piezoelectric layer including a plurality of layers, the piezoelectric layer being formed adjacent to a top face of the first electrode, and a second electrode including at least one conductive layer, the second electrode being formed adjacent to a top face of the piezoelectric layer. The acoustic resonator is characterized in that the piezoelectric layer includes a tensile compression layer in which tensile stress is present and a compression stress layer in which compression stress is present, and the tensile stress in the tensile stress layer and the compression stress in the compression stress layer are adjusted to cancel each other.

In the acoustic resonator of the present invention, the piezoelectric layer includes a tensile compression layer in which tensile stress is present and a compression stress layer in which compression stress is present, and the tensile stress in the tensile stress layer and the compression stress in the compression stress layer are adjusted to cancel each other. The occurrence of a large bent of a piezoelectric layer in which only tensile stress or compression stress is present is prevented, and the electromechanical coupling coefficient is increased.

An acoustic-resonator fabricating method of the present invention is a method of fabricating an acoustic resonator including a first electrode including at least one conductive layer, a piezoelectric layer including a plurality of layers, the piezoelectric layer being formed adjacent to a top face of the electrode, and a second electrode including at least one conductive layer, the second electrode being formed adjacent to a top face of the piezoelectric layer. The method is characterized in that a step of forming the piezoelectric layer includes a step of forming a tensile stress layer in which tensile stress is present and a step of forming a compression stress layer in which compression stress is present, and the tensile stress layer and the compression stress layer are formed so that the tensile stress in the tensile stress layer and the compression stress in the compression stress layer cancel each other.

In the acoustic-resonator fabricating method of the present invention, a step of forming the piezoelectric layer includes a step of forming a tensile stress layer in which tensile stress is present and a step of forming a compression stress layer in which compression stress is present, and the tensile stress layer and the compression stress layer are formed so that the tensile stress in the tensile stress layer and the compression stress in the compression stress layer cancel each other. The occurrence of a large bent of a piezoelectric layer in which only tensile stress or compression stress is present is prevented, and the electromechanical coupling coefficient is increased.

In the acoustic resonator of the present invention, the piezoelectric layer includes a tensile compression layer in which tensile stress is present and a compression stress layer in which compression stress is present, and the tensile stress in the tensile stress layer and the compression stress in the compression stress layer are adjusted to cancel each other. The occurrence of a large bent of a piezoelectric layer in which only tensile stress or compression stress is present is prevented, and the electromechanical coupling coefficient is increased. There is an advantage that an acoustic resonator with a high Q value can be realized. Accordingly, a high-quality band-pass filter with a wide frequency pass-band and low insertion loss can be provided.

The acoustic-resonator fabricating method of the present invention forms a tensile stress layer in which tensile stress is present and a compression stress layer in which compression stress is present. Since the tensile stress layer and the compression stress layer are formed so that tensile stress in the tensile stress layer cancels compression stress in the compression stress layer, the occurrence of a large bent of a piezoelectric layer in which only tensile stress or compression stress is present can be prevented, and the electromechanical coupling coefficient can be increased. There is an advantage that the acoustic resonator 1 with a high Q value can be realized. Accordingly, there is an advantage that a high-quality band-pass filter with a wide frequency pass-band and low insertion loss can be fabricated at a high yield.

### BRIEF DESCRIPTION OF DRAWINGS

FIG. 1 includes drawings illustrating a first embodiment of an embodiment according to an acoustic resonator of the present invention, that is, part (1) of FIG. 1 is a sectional view schematically showing the structure of the acoustic resonator, and part (2) of FIG. 1 is an enlarged sectional view of a piezoelectric layer.

FIG. 2 includes sectional views schematically showing the structure of a piezoelectric layer in second and third embodiments of the embodiment according to the acoustic resonator of the present invention.

FIG. 3 includes drawings of comparison of characteristics of the acoustic resonators in the first to third embodiments with characteristics of an acoustic resonator including a piezoelectric layer with a known structure.

FIG. 4 includes manufacturing-step sectional views illustrating an embodiment of an embodiment according to an acoustic-resonator fabricating method of the present invention.

FIG. 5 includes manufacturing-step sectional views illustrating the embodiment of the embodiment according to the acoustic-resonator fabricating method of the present invention.

FIG. 6 is a sectional view schematically illustrating the structure of a known air-bridge FBAR.

FIG. 7 is a sectional view schematically illustrating a problem of the known air-bridge FBAR.

FIG. 8 is a plan layout view illustrating the problem of the known air-bridge FBAR.

FIG. 9 includes a sectional view schematically illustrating the structure of the known air-bridge FBAR.

### BEST MODE FOR CARRYING OUT THE INVENTION

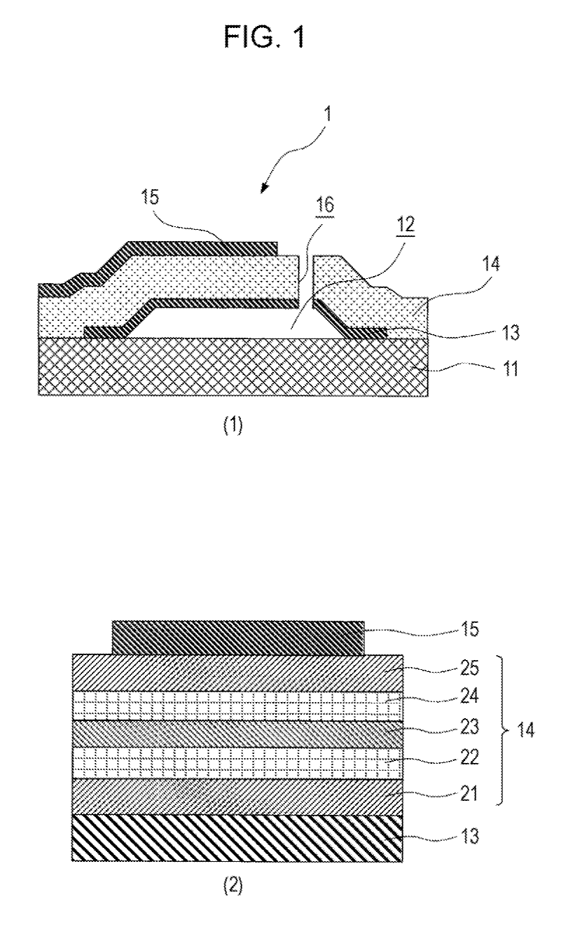

A first embodiment of an embodiment according to an acoustic resonator of the present invention will be described using FIG. 1. Part (1) of FIG. 1 is a sectional view schematically illustrating the structure of the acoustic resonator, and part (2) of FIG. 1 illustrates an enlarged sectional view of a piezoelectric layer.

As shown in FIG. 1, a first electrode (lower electrode) 13 is formed on the top face of a supporting substrate 11 so as to cover an air layer 12. That is, the air layer 12 is enclosed by the first electrode 13. The first electrode 13 is made of, for example, molybdenum (Mo) and is formed to have a thickness of, for example, 230 nm. The first electrode 13 may be formed using, besides molybdenum, a metal material such as tungsten, tantalum, titanium, platinum, ruthenium, gold, aluminum, copper, or the like. The first electrode 13 may alternatively be formed of a plurality of layers made of the electrode material.

A piezoelectric layer 14 is formed on the first electrode 13. The piezoelectric layer 14 is an aluminum nitride (AlN) film having a plurality of layers in which internal stress is replaced and is formed to have a thickness of, for example, 1.0 μm. Since the resonant frequency of the acoustic resonator (FBAR) is substantially determined by the thickness of the piezoelectric layer 14, the thickness of the piezoelectric layer 14 is determined according to the resonant frequency of the acoustic resonator.

The piezoelectric layer 14 is formed by sequentially stacking, for example, starting from the bottom layer (the first electrode 13 side), a compression stress layer 21, a buffer layer 22, a tensile stress layer 23, a buffer layer 24, and a compression stress layer 25. The buffer layer 22 is provided between the compression stress layer 21 and the tensile stress layer 23 and is formed to alleviate compression stress in the compression stress layer 21 and tensile stress in the tensile stress layer 23. The buffer layer 22 is formed using, for example, an aluminum nitride layer having 0 stress or, for example, tensile stress or compression stress of less than 100 MPa. Similarly, the buffer layer 24 is provided between the tensile stress layer 23 and the compression stress layer 25 and is formed to alleviate tensile stress in the tensile stress layer 23 and compression stress in the compression stress layer 25. The buffer layer 24 is formed using, for example, an aluminum nitride layer having 0 stress or, for example, tensile stress or compression stress of less than 100 MPa. In addition, the compression stress layers 21 and 25 are formed to have compression stress of, for example, 300 MPa or greater or, preferably, 1 GPa or greater. Also, the tensile stress layer 23 is formed to have tensile stress of 300 MPa or greater or, preferably, 800 MPa or greater.

The thickness of the layers is, for example, as follows. The compression stress layers 21 and 25 have a thickness of 100 nm. The buffer layers 22 and 24 have a thickness of 200 nm. The tensile stress layer 23 has a thickness of 400 nm. Thus, the thickness of the entire piezoelectric layer 14 is 1 μm, as has been described above.

The piezoelectric layer 14 is in a state where compression stress induced in the compression stress layers 21 and 25 cancels tensile stress induced in the tensile stress layer 23. Thus, the entirety of the piezoelectric layer 14 is formed so that compression stress and tensile stress cancel each other. The thickness and stress in the compression stress layers 21 and 25 and the tensile stress layer 23 are adjusted so that compression stress and tensile stress cancel each other in this manner.

Furthermore, in order that the piezoelectric layer 14 obtains sufficient piezoelectric characteristics, the aluminum nitride (AlN) layers are aligned in the c-axis direction as much as possible. Regarding the tolerance, for example, a half-width in the c-axis direction is preferably within 1.5 degrees.

An upper electrode 15 is formed on the piezoelectric layer 14. The upper electrode 15 is made of, for example, molybdenum (Mo), and is formed to have a thickness of, for example, 334 nm. The upper electrode layer may be formed using, besides molybdenum, a metal material such as tungsten, tantalum, titanium, platinum, ruthenium, gold, aluminum, copper, or the like. The upper electrode layer may alternatively be formed of a plurality of layers made of the electrode material.

In addition, a via hole 32 penetrating through the piezoelectric layer 14 and the first electrode 13 and reaching the air layer 12 is formed. The via hole 32 is used to etch a sacrificial layer for forming the air layer 12, which will be described in detail later in a description of a fabrication method.

As has been described above, a so-called air-bridge acoustic resonator (FBAR) 1 is configured.

In the acoustic resonator 1, the piezoelectric layer 14 includes the tensile stress layer 23 in which tensile stress is present and the compression stress layers 21 and 25 in which compression stress is present. Also, since adjustment is made so that tensile stress in the tensile stress layer 23 and compression stress in the compression stress layers 21 and 25 cancel each other, the occurrence of a large bent of a piezoelectric layer in which only tensile stress or compression stress is present can be prevented, and the electromechanical coupling coefficient can be increased. There is an advantage that the acoustic resonator 1 with a high Q value can be realized. Accordingly, a high-quality band-pass filter with a wide frequency pass-band and low insertion loss can be provided. By the way, a band-pass filter using the acoustic resonator 1 of the present invention could achieve a 10-MHz increase in the bandwidth in the case where a center frequency is 2 GHz band.

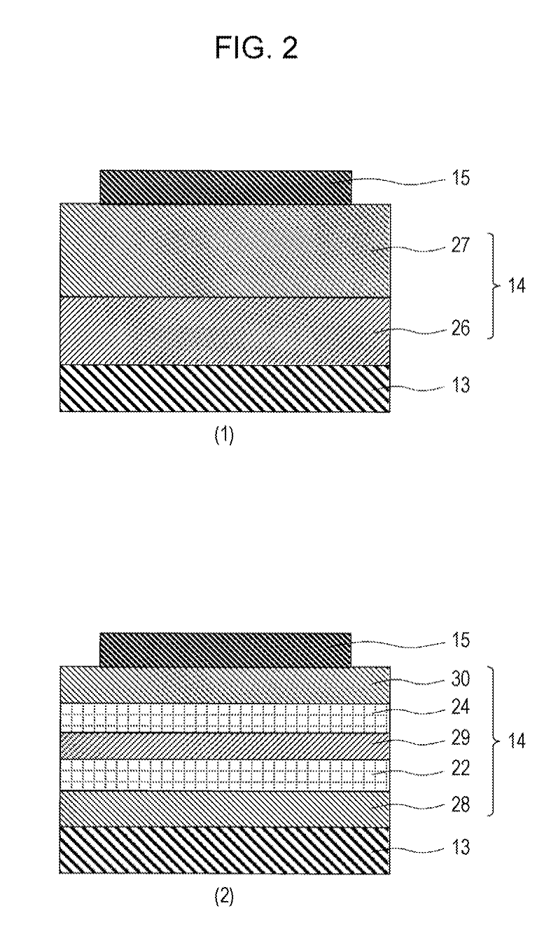

Second and third embodiments of the embodiment according to the acoustic resonator of the present invention will be described using schematic sectional views of FIG. 2. Part (1) of FIG. 2 illustrates a piezoelectric layer of the second embodiment, and part (2) of FIG. 2 illustrates a piezoelectric layer of the third embodiment.

As shown in part (1) of FIG. 2, an acoustic resonator of the second embodiment has a structure similar to the foregoing acoustic resonator 1 except for the structure of the piezoelectric layer 14. Thus, the structure of the piezoelectric layer 14 will herein be described. The piezoelectric layer 14 is formed by staking, on the first electrode 13 formed on the supporting substrate 11 so as to cover the air layer 12, which has been described using FIG. 1, a compression stress layer 26 having compression stress and a tensile stress layer 27 having tensile stress, which is formed on the compression stress layer 26. Furthermore, the upper electrode 15 is formed on the tensile stress layer 27.

The thickness of the layers is, for example, as follows. The compression stress layer 26 has a thickness of 500 nm. The tensile stress layer 27 has a thickness of 500 nm. Thus, the thickness of the entire piezoelectric layer 14 is 1 μm.

In addition, the piezoelectric layer 14 is in a state where compression stress induced in the compression stress layer 26 cancels tensile stress induced in the tensile stress layer 27. Thus, the entirety of the piezoelectric layer 14 is formed so that compression stress and tensile stress cancel each other. The thickness and stress in the compression stress layer 26 and the tensile stress layer 27 are adjusted so that compression stress and tensile stress cancel each other in this manner.

Even the acoustic resonator having the structure of the piezoelectric layer 14 as shown in part (1) of FIG. 2 can achieve the operation and advantages similar to those of the foregoing acoustic resonator 1.

As shown in part (2) of FIG. 2, an acoustic resonator of the third embodiment has a structure similar to the foregoing acoustic resonator 1 except for the structure of the piezoelectric layer 14. Thus, the structure of the piezoelectric layer 14 will herein be described. The piezoelectric layer 14 is formed by sequentially staking, on the first electrode 13 formed on the supporting substrate 11 so as to cover the air layer 12, which has been described using FIG. 1, a tensile stress layer 28, the buffer layer 22, a compression stress layer 29, the buffer layer 24, and a tensile stress layer 30. The buffer layer 22 is provided between the tensile stress layer 28 and the compression stress layer 29 and is formed to alleviate tensile stress in the tensile stress layer 28 and compression stress in the compression stress layer 29. The buffer layer 22 is formed using, for example, an aluminum nitride layer having 0 stress or, for example, tensile stress or compression stress of 100 MPa or less. Similarly, the buffer layer 24 is provided between the compression stress layer 29 and the tensile stress layer 30 and is formed to alleviate compression stress in the compression stress layer 29 and tensile stress in the tensile stress layer 30. The buffer layer 24 is formed using, for example, an aluminum nitride layer having 0 stress or, for example, tensile stress or compression stress of less than 100 MPa. In addition, the compression stress layer 29 is formed to have compression stress of, for example, 300 MPa or greater or, preferably, 600 MPa or greater. Also, the tensile stress layers 28 and 30 are formed to have tensile stress of 300 MPa or greater or, preferably, 800 MPa or greater.

The thickness of the layers is, for example, as follows. The tensile stress layers 28 and 30 have a thickness of 100 nm. The buffer layers 22 and 24 have a thickness of 200 nm. The compression stress layer 29 has a thickness of 400 nm. Thus, the thickness of the entire piezoelectric layer 14 is 1 μm.

The piezoelectric layer 14 is in a state where tensile stress induced in the tensile stress layers 28 and 30 cancels compression stress induced in the compression stress layer 29. Thus, the entirety of the piezoelectric layer 14 is formed so that tensile stress and compression stress cancel each other. The thickness and stress in the tensile stress layers 28 and 30 and the compression stress layer 29 are adjusted so that tensile stress and compression stress cancel each other in this manner.

Even the acoustic resonator having the structure of the piezoelectric layer 14 as shown in part (2) of FIG. 2 can achieve the operation and advantages similar to those of the foregoing acoustic resonator 1.

Also, the piezoelectric layer 14 of the acoustic resonator described above preferably includes the compression stress 21 or 26 on the first electrode (lower electrode) 13, as in the first embodiment and the second embodiment. In this manner, crystal growth of the piezoelectric layer 14 starts from the compression stress layer 21 or 26, and hence the crystal orientation of the entire piezoelectric layer 14 is improved. For example, in the case of aluminum nitride (AlN), orientation in the c-axis direction is demanded to promote crystal growth with excellent orientation. To this end, it is necessary to form, at first, as a film in which crystal growth starts, a compression stress film that is apt to be preferably oriented in the c-axis direction. When the tensile stress layer 28 is formed at first, the tensile stress layer 28 is difficult to be oriented in the c-axis direction. As in the foregoing third embodiment, the electromechanical coupling coefficient of the acoustic resonator is slightly reduced. This point will be described as follows.

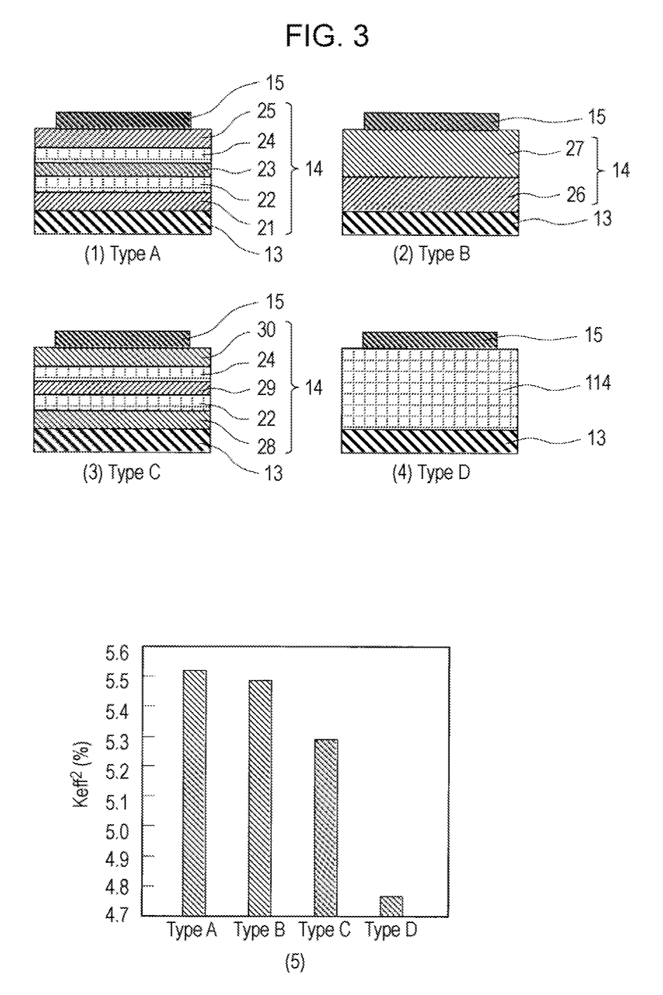

Next, the characteristics of the acoustic resonators of the first to third embodiments are compared with the characteristics of an acoustic resonator with a piezoelectric layer with a known structure. The results will be described using FIG. 3.

As shown in part (1) of FIG. 3, in an acoustic resonator of Type A, the piezoelectric layer 14 is formed by sequentially stacking, starting from the first electrode (lower electrode) 13 side, the compression stress layer 21, the buffer layer 22, the tensile stress layer 23, the buffer layer 24, and the compression stress layer 25. The second electrode (upper electrode) 15 is formed on the compression stress layer 25. The details of these elements have been explained above using FIG. 1.

As shown in part (2) of FIG. 3, in an acoustic resonator of Type B, the piezoelectric layer 14 is formed by sequentially stacking, starting from the first electrode (lower electrode) 13 side, the compression stress layer 26 and the tensile stress layer 27. The second electrode (upper electrode) 15 is formed on the tensile stress layer 27. The details of these elements have been explained above using part (1) of FIG. 2.

As shown in part (3) of FIG. 3, in an acoustic resonator of Type C, the piezoelectric layer 14 is formed by sequentially stacking, starting from the first electrode (lower electrode) 13 side, the tensile stress layer 28, the buffer layer 22, the compression stress layer 29, the buffer layer 24, and the tensile stress layer 30. The second electrode (upper electrode) 15 is formed on the tensile stress layer 30. The details of these elements have been explained above using part (2) of FIG. 2.

As shown in part (4) of FIG. 3, an acoustic resonator of Type D is an acoustic resonator with a known structure. A piezoelectric layer 114 is formed of, on the first electrode (lower electrode) 13, an aluminum nitride layer that is made of a material similar to that used to form the foregoing buffer layers and that uniformly has, for example, 0 stress or, for example, tensile stress or compression stress of less than 100 MPa. The second electrode (upper electrode) 15 is formed on the piezoelectric layer 114.

Next, the relationship with the electromechanical coupling coefficients of the acoustic resonators having the piezoelectric layers 14 with the structure of internal stress shown in Types A, B, C, and D, as have been described above, will be described using part (5) of FIG. 3. Measured values are values measured using FBARs with the foregoing piezoelectric layers. The type and value of internal stress in each piezoelectric layer were determined by examining the direction and amount of warp of the substrate generated by depositing aluminum nitride (AlN) layers on the substrate. Also, the electromechanical coupling coefficient was measured using an FBAR in which the electric capacitance of an overlap area of the first electrode 13 and the second electrode 15 is 1.1 pF.

As shown in part (5) of FIG. 3, the acoustic resonator with the structure in which the piezoelectric layer 14 of the present invention includes a tensile stress layer in which tensile stress is present and a compression stress layer in which compression stress is present and tensile stress in the tensile stress layer and compression stress in the compression stress layer are adjusted to cancel each other has an electromechanical coupling coefficient (Keff²) greater than that of the acoustic resonator with the structure of the known piezoelectric layer 114. The larger the value of the electromechanical coupling coefficient, the larger the difference between the resonant frequency and the anti-resonant frequency of the acoustic resonator (e.g., FBAR). When a band-pass filter is configured, there is an advantage that a wide frequency pass-band can be achieved. It is thus generally required to ensure that the electromechanical coupling coefficient is 5.0 or greater. Therefore, every one of Type A (the structure of the first embodiment), Type B (the structure of the second embodiment), and Type C (the structure of the third embodiment) having the structure of the piezoelectric layer 14 of the present invention has an electromechanical coupling coefficient of 5.0 or greater. Compared with the acoustic resonator with the structure of the known piezoelectric layer 114, the electromechanical coupling coefficient (Keff²) is significantly improved.

Furthermore, in every one of Type A, Type B, and Type C, the occurrence of cracks is suppressed. Both the filter characteristics and the yield are achieved.

In Type C of the third embodiment, since the crystal orientation of the tensile stress layer 26 deposited at first is not oriented in the c-axis direction, the electromechanical coupling coefficient is lower than that of the acoustic resonators of the first embodiment and the second embodiment. Therefore, it is preferable that a film deposited at first on the first electrode 13 be a film with compression stress. The orientation in the case where the internal stress in the bottom layer of the piezoelectric layer 14, which is adjacent to the top face of the first electrode (lower electrode) 13, is adjusted to be compression stress is within 1.5 degrees. Excellent orientation is reflected in the electromechanical coupling coefficient.

As has been described above, it is preferable that compression stress and tensile stress simultaneously exist in the piezoelectric layer 14, and that compression stress and tensile stress are in a state where compression stress and tensile stress cancel each other.

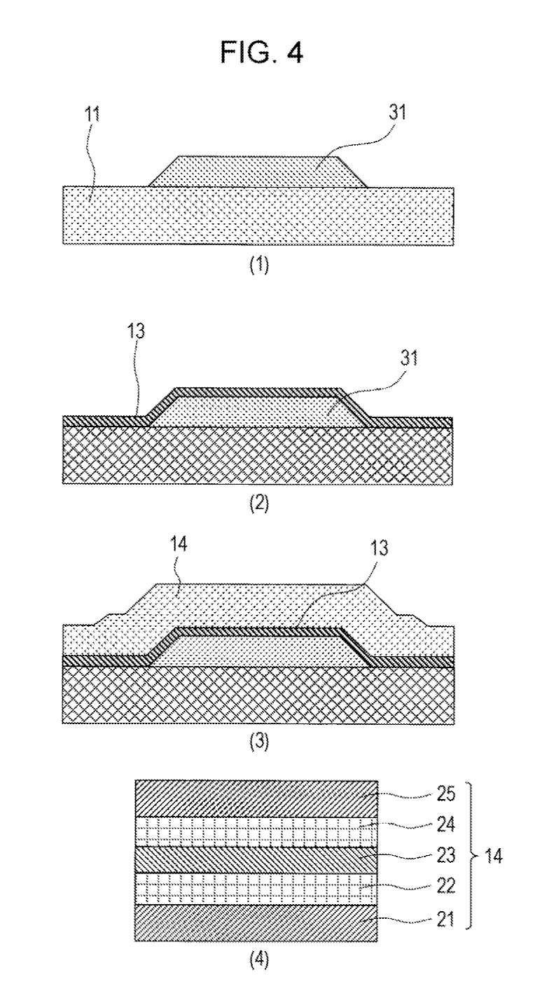

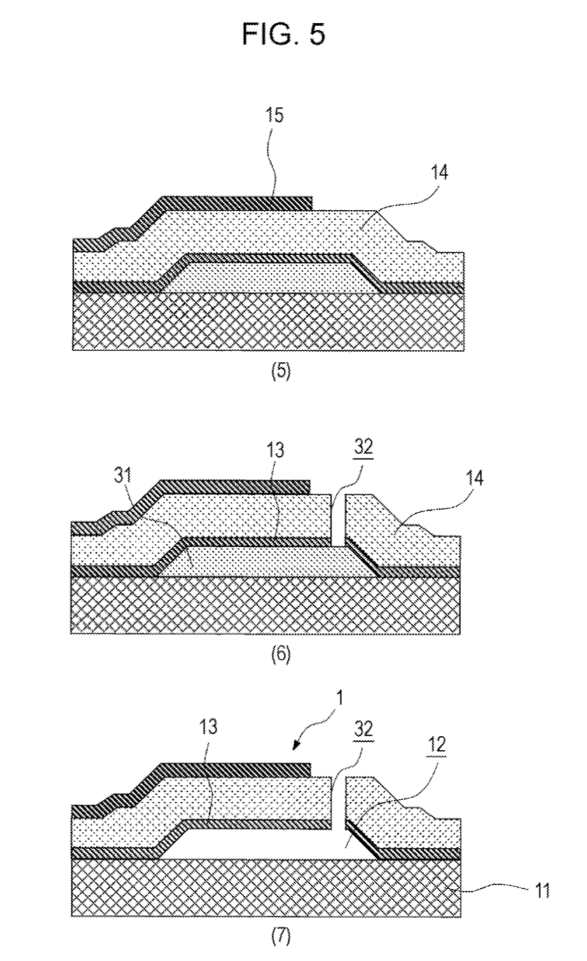

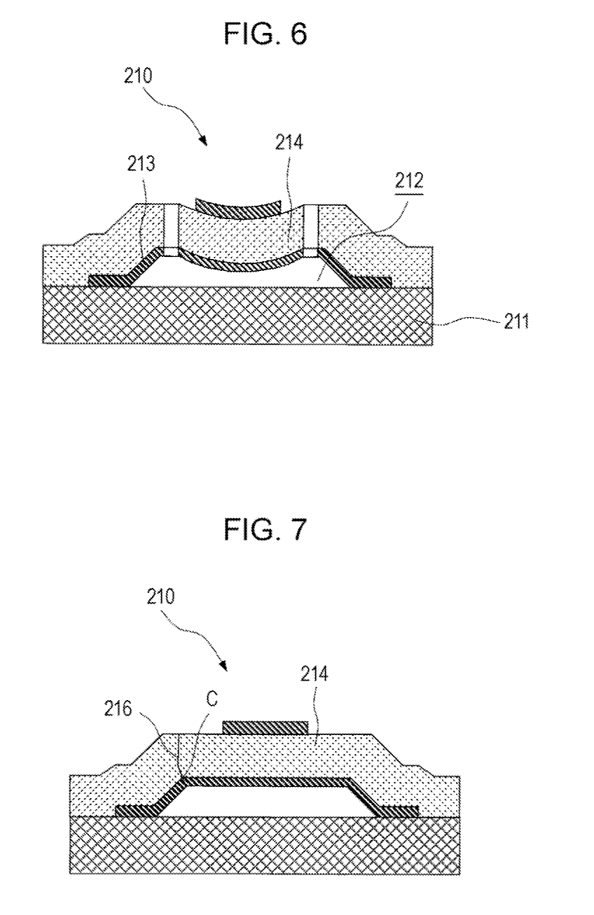

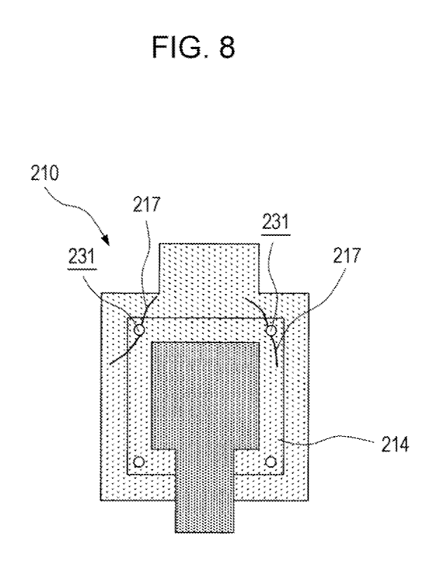

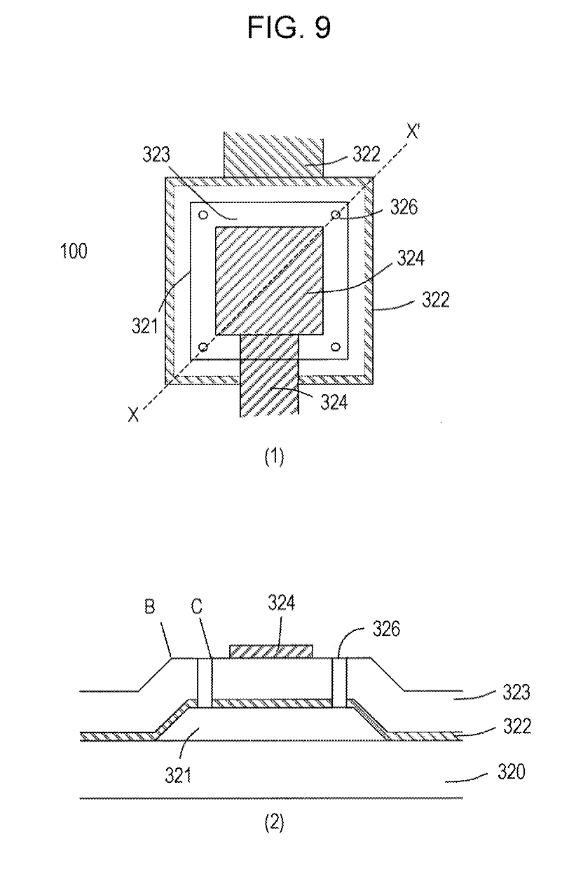

Next, an embodiment of an embodiment according to an acoustic-resonator fabricating method of the present invention will be described using manufacturing-step sectional views of FIGS. 4 and 5.

As shown in part (1) of FIG. 4, after a sacrificial layer is deposited on the top face of the supporting substrate 11 in order to form an air layer in the subsequent step, a resist mask is formed using the general lithography technique and the sacrificial layer is patterned with the etching technique using the resist mask, thereby forming a sacrificial layer pattern 31. The sacrificial layer pattern 31 is formed as, for example, a prismoid. The sacrificial layer pattern 31 is formed using, for example, a silicon oxide film that can be etched using, for example, fluorine. For example, an SOG (Spin on glass) film is deposited to have a thickness of 1 μn. Alternatively, the sacrificial layer pattern 31 can be formed as, using a CVD method, a silicon oxide film, a phosphosilicate glass (PSG) film, a borophosphosilicate glass (BPSG) film, or the like.

Next, as shown in part (2) of FIG. 4, the first electrode (lower electrode) 13 is formed on the supporting substrate 11 so as to cover the sacrificial layer pattern 31. The first electrode 13 is formed by depositing, for example, molybdenum (Mo) at a thickness of, for example, 230 nm using, for example, a DC magnetron sputtering method or the like. The first electrode 13 may be formed using, besides molybdenum, a metal material such as tungsten, tantalum, titanium, platinum, ruthenium, gold, aluminum, copper, or the like. The first electrode 13 may alternatively be formed of a plurality of layers made of the electrode material.

Next, as shown in part (3) of FIG. 4, the piezoelectric layer 14 is formed on the first electrode 13. The piezoelectric layer 14 is, for example, an aluminum nitride (AlN) film having a plurality of layers in which internal stress is replaced and is formed to have a thickness of, for example, 1.0 μm using a DC pulse sputtering method or the like. Since the resonant frequency of the acoustic resonator (FBAR) is substantially determined by the thickness of the piezoelectric layer 14, the thickness of the piezoelectric layer 14 is determined according to the resonant frequency of the acoustic resonator.

For example, as shown in part (4) of FIG. 4, starting from the bottom layer, the compression stress layer 21, the buffer layer 22, the tensile stress layer 23, the buffer layer 24, and the compression stress layer 25 are sequentially formed. The buffer layer 22 is provided between the compression stress layer 21 and the tensile stress layer 23 and is formed to alleviate compression stress in the compression stress layer 21 and tensile stress in the tensile stress layer 23. The buffer layer 22 is formed using, for example, an aluminum nitride layer having 0 stress or, for example, tensile stress or compression stress of less than 100 MPa. Similarly, the buffer layer 24 is provided between the tensile stress layer 23 and the compression stress layer 25 and is formed to alleviate tensile stress in the tensile stress layer 23 and compression stress in the compression stress layer 25. The buffer layer 24 is formed using, for example, an aluminum nitride layer having 0 stress or, for example, tensile stress or compression stress of less than 100 MPa. In addition, the compression stress layers 21 and 25 are formed to have compression stress of, for example, 300 MPa or greater or, preferably, 1 GPa or greater. Also, the tensile stress layer 23 is formed to have tensile stress of 300 MPa or greater or, preferably, 800 MPa or greater.

The thickness of the layers is, for example, as follows. The compression stress layers 21 and 25 have a thickness of 100 nm. The buffer layers 22 and 24 have a thickness of 200 nm. The tensile stress layer 23 has a thickness of 400 nm. Thus, the thickness of the entire piezoelectric layer 14 is 1 μm, as has been described above.

The compression stress layer 21, the buffer layer 22, the tensile stress layer 23, the buffer layer 24, and the compression stress layer 25 can be consecutively deposited in the same chamber of a DC pulse sputtering apparatus. Film deposition conditions include a film deposition pressure of, for example, 0.27 Pa, a flow ratio of argon gas to nitrogen gas of, for example, 1:7, sputter power of, for example, 5 kW to 10 kW, and a substrate bias voltage of, for example, 25 V to 48 V. By changing the substrate bias voltage, stress in a deposited film is determined. When depositing the compression stress layers 21 and 25, the substrate bias voltage is set to, for example, 42 V to 48 V (e.g., 45 V). For example, the substrate bias voltage was set to 45 V to obtain compression stress of 800 MPa. Also, when forming the buffer layers 22 and 24, the substrate bias voltage is set to, for example, 31 V to 35 V. When forming the tensile stress layer 23, the substrate bias voltage is set to, for example, 22 V to 26 V. For example, the substrate bias voltage was set to 26 V to obtain tensile stress of 550 MPa. By adjusting the substrate bias voltage in this manner, the compression stress layers 21 and 25, the buffer layers 22 and 24 where stress is 0 or substantially 0, and the tensile stress layer 23 can be formed to configure a multilayer structure, as has been described above. Moreover, a state in which compression stress induced in the compression stress layers 21 and 25 and tensile stress induced in the tensile stress layer 23 cancel each other can be achieved. In order to form the entirety of the piezoelectric layer 14 so that compression stress and tensile stress cancel each other in this manner, it is important to deposit films by adjusting the film thickness and stress in the compression stress layers 21 and 25 and the tensile stress layer 23.

Alternatively, in the case where the piezoelectric layer 14 is configured by stacking the compression stress layer 26 and the tensile stress layer 27, which have been described using part (1) of FIG. 2, the piezoelectric layer 14 may be formed by changing the substrate bias voltage and sequentially stacking the compression stress layer 26 and the tensile stress layer 27. Similarly, in the case where the piezoelectric layer 14 is configured by stacking the tensile stress layer 28, the buffer layer 22, the compression stress layer 29, the buffer layer 24, and the tensile stress layer 30, which have been described using part (2) of FIG. 2, the piezoelectric layer 14 may be formed by changing the substrate bias voltage and sequentially stacking the tensile stress layer 28, the buffer layer 22, the compression stress layer 29, the buffer layer 24, and the tensile stress layer 30.

Furthermore, in the foregoing film deposition, the aluminum nitride (AlN) layers are required to be aligned in the c-axis direction as much as possible in order to enable the piezoelectric layer 14 to achieve sufficient piezoelectric characteristics. Regarding the tolerance, for example, a half-width in the c-axis direction is preferably within 1.5 degrees.

Next, as shown in part (5) of FIG. 5, an upper electrode layer for forming an upper electrode on the piezoelectric layer 14 is formed. The upper electrode layer is formed by depositing, for example, molybdenum (Mo) at a thickness of, for example, 334 nm using, for example, the DC magnetron sputtering method. The upper electrode layer may be formed using, besides molybdenum, a metal material such as tungsten, tantalum, titanium, platinum, ruthenium, gold, aluminum, copper, or the like. The upper electrode layer may alternatively be formed of a plurality of layers made of the electrode material. Thereafter, a resist mask (not shown) for forming the upper electrode is formed using the resist coating and the lithography technique. After that, the upper electrode layer is patterned with the etching technique using the resist mask, thereby forming the upper electrode 15. This etching is performed as, for example, reactive ion etching (RIE) using halogen gas as etching gas. Thereafter, the resist mask is removed.

Next, as shown in part (6) of FIG. 5, a resist mask (not shown) for forming a via hole required to remove the sacrificial layer pattern 31 is formed using the resist coating and the lithography technique. After that, the via hole 32 penetrating through the piezoelectric layer 14 and the lower electrode 13 and reaching the sacrificial layer pattern 31 is formed with the etching technique using the resist mask. This etching is performed as, for example, reactive ion etching (RIE) using halogen gas as etching gas.

Next, as shown in part (7) of FIG. 5, the resist mask is removed. Thereafter, the sacrificial layer pattern 31 [see part (6) of FIG. 4 described above] is removed via the via hole 32. The removing processing of the sacrificial layer pattern 31 is performed by wet etching using, for example, a fluoride (HF) solution. The sacrificial layer pattern 31 is completely removed by performing this etching, and a space 12 is formed in this removed portion. That is, the space 12 is formed between the supporting substrate 11 and the first electrode 13. In this manner, the so-called air-bridge acoustic resonator (FBAR) 1 is completed.

The foregoing acoustic-resonator fabricating method forms the tensile stress layer 23 in which tensile stress is present and the compression stress layers 21 and 25 in which compression stress is present. Since the tensile stress layer 23 and the compression stress layers 21 and 25 are formed so that tensile stress in the tensile stress layer 21 cancels compression stress in the compression stress layers 21 and 25, the occurrence of a large bent of a piezoelectric layer in which only tensile stress or compression stress is present can be prevented, and the electromechanical coupling coefficient can be increased. There is an advantage that the acoustic resonator 1 with a high Q value can be realized. Accordingly, there is an advantage that a high-quality band-pass filter with a wide frequency pass-band and low insertion loss can be fabricated at a high yield.

Furthermore, although the air-bridge acoustic resonator (e.g., FBAR) has been described by way of example in the present embodiment, according to the invention of the subject application, the advantages of the present invention can be achieved as long as the piezoelectric layer 14 includes a compression stress layer and a tensile stress layer and stress adjustment is done so that compression stress and tensile stress cancel each other, regardless of the position at which the FBAR is formed on the supporting substrate or the structure thereof. Therefore, a membrane FBAR described in document 1 and an FBAR configured with an acoustic reflection mirror are expected to achieve similar advantages.

1-5. (canceled)

6. An acoustic resonator comprising a first electrode including at least one conductive layer, a piezoelectric layer including a plurality of layers, the piezoelectric layer being formed adjacent to a top face of the first electrode, and a second electrode including at least one conductive layer, the second electrode being formed adjacent to a top face of the piezoelectric layer, wherein:
the piezoelectric layer includes a tensile compression layer in which tensile stress is present and a compression stress layer in which compression stress is present, and
the tensile stress in the tensile stress layer and the compression stress in the compression stress layer are adjusted to cancel each other.

7. The acoustic resonator according to claim 6, wherein a buffer layer for alleviating the compression stress in the compression stress layer and the tensile stress in the tensile stress layer is formed between the compression stress layer and the tensile stress layer.

8. The acoustic resonator according to claim 6, wherein:
the first electrode is formed on a substrate with an air layer provided partially therebetween, and
one layer of the compression stress layer is formed adjacent to the first electrode.

9. The acoustic resonator according to claim 6, wherein the piezoelectric layer is formed of aluminum nitride or zinc oxide.

10. A method of fabricating an acoustic resonator including a first electrode including at least one conductive layer, a piezoelectric layer including a plurality of layers, the piezoelectric layer being formed adjacent to a top face of the electrode, and a second electrode including at least one conductive layer, the second electrode being formed adjacent to a top face of the piezoelectric layer, wherein:
a step of forming the piezoelectric layer includes
a step of forming a tensile stress layer in which tensile stress is present, and
a step of forming a compression stress layer in which compression stress is present, and
the tensile stress layer and the compression stress layer are formed so that the tensile stress in the tensile stress layer and the compression stress in the compression stress layer cancel each other.
